(19) United States
(12) Patent Application Publication
(10) Pub. No.: US 2025/0192053 A1
(43) Pub. Date: Jun. 12, 2025

(54) INTERCONNECT STRUCTURE, AND ELECTRONIC DEVICE INCLUDING SAME

(71) Applicants: SAMSUNG ELECTRONICS CO., LTD., Suwon-si (KR); AJOU UNIVERSITY INDUSTRY-ACADEMIC COOPERATION FOUNDATION, Suwon-si (KR)

(72) Inventors: GIYOUNG JO, Suwon-si (KR); Sang Woon LEE, Suwon-si (KR); Sangwon KIM, Suwon-si (KR); Daejin YANG, Suwon-si (KR); Sangmo MOON, Suwon-si (KR); Juyoung SUNG, Suwon-si (KR); Chaehyun LEE, Suwon-si (KR)

(21) Appl. No.: 18/967,882

(22) Filed: Dec. 4, 2024

(30) Foreign Application Priority Data
Dec. 6, 2023 (KR) 10-2023-0175556

(51) Int. Cl. H01L 23/532

(52) U.S. Cl. CPC H01L 23/53247; H01L 23/53219; H01L 23/53223; H01L 23/53252; H01L 23/53261; H01L 23/53266

(57) ABSTRACT

An interconnect structure including a dielectric layer; a conductive wiring including a first cobalt-metal alloy within a trench structure of the dielectric layer; and a cobalt-containing auxiliary layer between the conductive wiring and the dielectric layer, wherein the cobalt-containing auxiliary layer includes cobalt or a second cobalt-metal alloy.

### CROSS-REFERENCE TO RELATED APPLICATION

This application claims priority to Korean Patent Application No. 10-2023-0175556 filed in the Korean Intellectual Property Office on Dec. 6, 2023, and all the benefits accruing therefrom under 35 U.D.C. § 119, the entire content of which is herein incorporated by reference.

### BACKGROUND

### 1. Field

The present disclosure relates to an interconnect structure and an electronic device including the interconnect structure.

### 2. Description of the Related Art

In order to provide high-density, high-performance semiconductor devices, efforts are continuing to reduce the line width or thickness of metal wiring. By reducing the line width, e.g., by reducing a thickness of metal wiring, the number of semiconductor chips integrated per unit wafer can be increased. Additionally, by reducing the thickness of the metal wiring, one would expect the capacitance of the line (wire) to decrease, and thus the speed of the signal passing through the wiring would increase.

On the other hand, as the line width or thickness of the metal wiring decreases, the resistance of the wire can rapidly increase, and therefore, reducing the resistance of the metal wire can become more important than a reduction in capacitance or an increase in chip density. Current wiring technology has a problem in that resistivity increases significantly due to grain-boundary scattering and/or surface-roughness scattering as line widths of the wiring are reduced. Additionally, because deterioration may occur due to oxidation occurring at the metal/oxide interface or exposed metal surface, a technology to reduce the resistance of the wiring structure while preventing metal oxidation of the surface of the wiring.

### SUMMARY

An embodiment provides an interconnect structure capable of reducing or minimizing an increase in resistance of the metal wiring resulting from a decrease in the line width of the metal wiring.

Another embodiment provides an electronic device including the interconnect structure.

According to an embodiment, an interconnect structure includes a dielectric layer; a conductive wiring including a first cobalt-metal alloy within a trench structure of the dielectric layer; and a cobalt-containing auxiliary layer between the conductive wiring and the dielectric layer, wherein the cobalt-containing auxiliary layer includes cobalt or a second cobalt-metal alloy.

The dielectric layer may include a dielectric having a dielectric constant of less than or equal to about 3.6.

The dielectric layer may include a metal oxide, a carbon-doped metal oxide, a metal carbide, a hydrogenated metal carbide, a metal nitride, a metal oxynitride, or a combination thereof.

The dielectric layer may include Al₂O₃, AlN, ZrOₓ (0<x≤2), HfOₓ (0<x≤2), SiO₂, SiCO, SiCN, SION, SiCOH, AlSiO, BN, or a combination thereof.

The dielectric layer may include a Group 3A (Group 13) element, a Group 4A (Group 14) element, a Group 4B (Group 4) element, or a combination thereof.

The first cobalt-metal alloy may be represented by Chemical Formula 1. Chemical Formula 1

Co₁₋ₓM¹ₓ

In Chemical Formula 1,

M¹ is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and 0<x<1.

The first cobalt-metal alloy and the second cobalt-metal alloy may have the same or different alloy compositions.

The first cobalt-metal alloy of the conductive wiring and the cobalt or second cobalt-metal alloy of the cobalt-containing auxiliary layer may have the same crystal structure.

The first cobalt-metal alloy may have a cohesive energy of greater than or equal to about 4.5 eV/atom.

The first cobalt-metal alloy may have a figure of merit (FOM) of less than or equal to about 5.0×10⁻¹⁶ Ωm².

The cobalt-containing auxiliary layer may include cobalt or a second cobalt-metal alloy represented by Chemical Formula 2.

Co_{1-y}M²_{y} Chemical Formula 2

In Chemical Formula 2,

M² is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and 0≤y<1.

The first cobalt-metal alloy included in the conductive wiring may have a hexagonal crystal structure (HCP) or a face-centered cubic crystal structure (FCC).

The cobalt-containing auxiliary layer may include cobalt having a hexagonal crystal structure or a second cobalt-metal alloy having a hexagonal crystal structure.

The cobalt-containing auxiliary layer may include cobalt or a second cobalt-metal alloy in which y in Chemical Formula 2 is greater than or equal to about 0 and less than about 1, and the conductive wiring may include a first cobalt-metal alloy having a hexagonal crystal structure (HCP) or a face-centered cubic crystal structure (FCC).

The cobalt-containing auxiliary layer may include cobalt or a second cobalt-metal alloy in which y of Chemical Formula 2 is in a range of greater than or equal to about 0 and less than about 0.25, and the conductive wiring may include a first cobalt-metal alloy having a hexagonal crystal structure (HCP).

The cobalt-containing auxiliary layer may include a second cobalt-metal alloy in which y of Chemical Formula 2 is in a range of greater than or equal to about 0.25 and less than or equal to about 0.3, and the conductive wiring may include a first cobalt-metal alloy having a hexagonal crystal structure (HCP) or a face-centered cubic crystal structure (FCC).

The cobalt-containing auxiliary layer may include a second cobalt-metal alloy in which y of Chemical Formula 2 is in a range of greater than about 0.3 and less than about 1, and the conductive wiring may include a first cobalt-metal alloy having a face-centered cubic crystal structure (FCC).

The second cobalt-metal alloy of the cobalt-containing auxiliary layer may include a greater atomic percent of cobalt than the atomic percent of cobalt of the first cobalt-metal alloy of the conductive wiring.

A difference between the atomic percent of cobalt in the second cobalt-metal alloy to the atomic percent of cobalt in the first cobalt-metal alloy may be greater than or equal to about 10 at %.

The cobalt-containing auxiliary layer may have a thickness of less than or equal to about 3 nm.

The trench structure of the dielectric layer may have a width of less than or equal to about 10 nm and an aspect ratio of greater than or equal to about 3.

The cobalt-containing auxiliary layer may be disposed on two sidewalls, or a bottom surface, or both of the conductive wiring.

A barrier layer may further be included between the cobalt-containing auxiliary layer and the dielectric layer along one or more sidewalls of the trench structure.

The barrier layer may include a metal, an alloy of a metal, a metal oxide, a metal nitride or a combination thereof.

According to another embodiment, an interconnect structure includes a dielectric layer; and a conductive wiring including a first cobalt-metal alloy within a trench structure of the dielectric layer, wherein the first cobalt metal alloy is represented by Chemical Formula 1A.

Co_{1-z}M¹_{z} Chemical Formula 1A

In Chemical Formula 1A,

M¹ is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and 0.2≤z<0.5.

In Chemical Formula 1A, x may be in a range of greater than or equal to about 0.3 and less than or equal to about 0.45.

A cobalt-containing auxiliary layer may further be included between the dielectric layer and the conductive wiring.

Another embodiment provides an electronic device including the interconnect structure.

The electronic device may be a transistor, a capacitor, a diode, or a resistor.

The interconnect structure can reduce or minimize an increase in resistance in the conductive wiring due to grain-boundary scattering and/or surface-roughness scattering as the line width of the metal wiring decreases.

### BRIEF DESCRIPTION OF THE DRAWINGS

FIGS. 1 to 5 are cross-sectional representations of various interconnect structures according to embodiments.

FIGS. 6 and 7 are cross-sectional representations of electronic devices according to embodiments.

FIG. 9 is a graph showing the resistance value relative to the x value of a cobalt-nickel alloy (Co₁₋ₓNiₓ) formed on a sapphire c-plane (0001) substrate.

FIG. 10 is a graph showing the resistance value relative to the x value of a cobalt-nickel alloy (Co₁₋ₓNiₓ) formed on a sapphire a-plane (1120) substrate.

FIG. 11 is a graph showing the results of resistance value measurements relative to the thickness of cobalt-nickel alloys formed on a quartz substrate.

FIG. 12A is a graph showing the results of elemental analysis of a stacked structure according to Example 2 using transmission electron microscopy-energy dispersive X-ray spectroscopy (TEM-EDS).

FIG. 12B is a drawing showing the crystal structure of a Co_{0.6}Ni_{0.4} alloy.

FIG. 12C is a graph showing the results of X-ray diffraction analysis of the Co_{0.6}Ni_{0.4} alloy.

FIG. 13A is a graph showing the results of elemental analysis of a stacked structure according to Example 3 using transmission electron microscopy-energy dispersive X-ray spectroscopy (TEM-EDS)

FIG. 13B is a drawing showing the crystal structure of a Co_{0.6}Ni_{0.4} alloy.

FIG. 13C is a graph showing the results of X-ray diffraction analysis of the Co_{0.6}Ni_{0.4} alloy.

FIG. 14 is a graph showing the results of resistance measurements relative to the thickness of stacked structures according to Comparative Example 1 and Examples 1, 2, and 3.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein. Moreover, the terminology used herein is used to describe embodiments only, and is not intended to limit the present disclosure.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer, or section from another element, component, region, layer, or section. Thus, “a first element,” “component,” “region,” “layer,” or “section” discussed below could be termed a second element, component, region, layer, or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items.

As used herein, terms such as “comprise,” “comprise,” “includes”, “with”, or “have” are intended to designate the presence of implemented features, numbers, steps, components, or a combination thereof, but not one or more other features, numbers, steps, components, or combinations thereof should be understood as not excluding in advance the existence or possibility of addition.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. In contrast, when an element is referred to as being “directly on” another element, there are no intervening elements present.

“About” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±5%, ±3%, or ±1% of the stated value.

Relative terms, such as “downward,” “lower,” or “bottom,” and “upward,” “upper,” or “top,” may be used herein to describe one element's relationship to another element as illustrated in the drawings. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In addition, “layer” herein includes not only a shape formed on the whole surface when viewed from a plan view, but also a shape formed on a partial surface.

The connections or connection members of lines between components shown in the drawings exemplify functional connections and/or physical or circuit connections, and in actual devices, may be represented as various functional connections, physical connections, or circuit connections.

As used herein, “at least one of A, B or C,” “one of A, B, C, or a combination thereof” and “one of A, B, C, and a combination thereof” refer to each component and refers to any combination (e.g., A; B; C; A and B; A and C; B and C; or A, B, and C).

Herein, “a combination thereof” means a mixture of components, a laminate, a composite, an alloy, a blend, and the like.

Herein, “metal” is interpreted as a concept that includes metals and metalloids (semimetals).

Hereinafter, an interconnect structure according to an embodiment will be described with reference to the attached drawings.

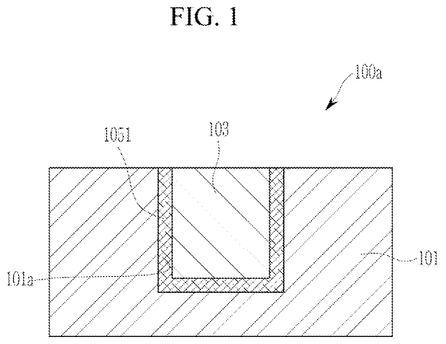

FIG. 1 is a cross-sectional view of an interconnect structure according to an embodiment.

Referring to FIG. 1, an interconnect structure 100a includes a dielectric layer 101 with a trench structure 101a; a cobalt-containing auxiliary layer 1051 disposed along a surface of the trench structure 101a; and a conductive wiring 103 including a first cobalt-metal alloy within the trench structure 101a.

A person of ordinary skill understands that the term “trench structure” present throughout the specification and in the claims is a term commonly used in the art of device or chip manufacturing. It is well understood in the art that a “trench structure” refers to a structural shape or contour within a dielectric layer that includes conductive wiring, e.g. a metal or metal alloy, that resides within the trench structure.

The interconnect structure 100a can be provided on a substrate (not shown) to constitute an electronic device. For example, the electronic device may include a DRAM or a logic device, and in this case, the interconnect structures 100a and 100b may be applied to a BEOL (Back End Of Line) structure of the DRAM or the logic device. In addition, the interconnect structure 100a can be applied to various electronic devices.

The substrate may be a semiconductor substrate. For example, the substrate may include a Group IV semiconductor material, a Group III-V semiconductor compound, or a Group II-VI semiconductor compound. That is, the substrate may include a Group IV semiconductor material including at least one of Si, Ge, Sn, and C, a Group III-V compound semiconductor material in which at least one of B, Ga, In, and Al is combined with at least one of N, P, As, Sb, S, Se, and Te, or a Group II-VI compound semiconductor material in which at least one of Be, Mg, Cd, and Zn is combined with at least one of O, S, Se, and Te. As specific examples, the substrate may include Si, Ge, SiC, SiGe, SiGeC, Ge alloy, GaAs, InAs, InP, and the like. However, this is only an example, and various other semiconductor materials can be used as substrates.

The substrate may include, for example, a Silicon-On-Insulator (SOI) substrate or a Silicon Germanium-On-Insulator (SGOI) substrate. Additionally, the substrate may include a non-doped semiconductor material or a doped semiconductor material.

The substrate may include at least one semiconductor device (not shown). The semiconductor device may include, for example, at least one of a transistor, a capacitor, a diode, and a resistor. However, the present disclosure is not limited thereto.

The dielectric layer 101 is formed on the substrate. This dielectric layer 101 may have a single-layer structure or a multilayer structure in which one or more different materials are stacked. The dielectric layer 101 may be an intermetallic dielectric (IMD) layer. The dielectric layer 110 may include, for example, a low-k dielectric material. For example, the dielectric layer 101 may include a dielectric having a dielectric constant of less than or equal to about 3.6, for example less than or equal to about 3.5, less than or equal to about 3.3, less than or equal to about 3.0, less than or equal to about 2.8, or less than or equal to about 2.7, and greater than or equal to about 0.01, for example greater than or equal to about 0.02, greater than or equal to about 0.03, greater than or equal to about 0.04, or greater than or equal to about 0.05. Here, the low-k material can mean a material with a lower dielectric constant (k) than silicon oxide (SiO₂). As the size of the device decreases, the spacing between conductive wirings 103 may decrease. Accordingly, the size of the dielectric layer 101 area disposed between two or more conductive wiring 103 is reduced, which may cause crosstalk that affects the performance of the device. By using a low-k material in the dielectric layer 101, parasitic capacitance affecting the performance of the device can be reduced, and also fast switching speed and low heat dissipation can be achieved.

In an embodiment, the dielectric layer 101 may include a metal oxide, a carbon-doped metal oxide, a metal carbide, a hydrogenated metal carbide, a metal nitride, a metal oxynitride, or a combination thereof. The dielectric layer 101 may include Al₂O₃, AlN, ZrOₓ (0<x≤2), HfOₓ (0<x≤2), SiO₂, SiCO, SiCN, SiON, SiCOH, AlSiO, BN (boron nitride), or a combination thereof.

The dielectric layer 101 may include a Group 3A (Group 13) element, a Group 4A (Group 14) element, a Group 4B (Group 4) element, or a combination thereof.

The dielectric layer 101 can be formed on a substrate through a deposition process used in a general semiconductor manufacturing process, such as chemical vapor deposition (CVD), plasma enhanced CVD (PECVD), or spin coating.

The above dielectric layer 101 may have a single-layer structure or a multilayer structure in which multiple layers including dielectrics are stacked.

The trench structure 101a may be formed in the dielectric layer 101 to a predetermined depth. Such a trench structure 101a can be formed, for example, through a photolithography process and an etching process. The trench structure 101a may have a line width of less than or equal to about 10 nm, for example, less than or equal to about 9 nm, less than or equal to about 8 nm, less than or equal to about 7 nm, or less than or equal to about 6 nm, and greater than or equal to about 1 nm. The line width of the trench structure 101a is measured from one sidewall to an opposite sidewall of the dielectric layer. The trench structure 101a may have an aspect ratio of greater than or equal to about 3, for example, greater than or equal to about 4, greater than or equal to about 5, or greater than or equal to about 6. The aspect ratio means the depth of the trench structure 101a divided by the width.

As shown, the cobalt-containing auxiliary layer 1051 is present along the side walls and along a bottom of the trench structure 101a of the dielectric layer 101, and a conductive wiring 103 is present within the trench structure 101a. FIG. 1 illustrates a structure in which a cobalt-containing auxiliary layer 1051 is formed on both sides and the bottom surface of a trench structure 101a, but the cobalt-containing auxiliary layer 1051 may be formed on one or more surfaces within the trench structure 101a. For example, it may be formed on one or both side walls or bottom surface within the trench structure 101a.

The conductive wiring 103 forms the wiring structure of the device and can be provided to fill, or partially fill, the interior volume of the trench structure 101a.

The conductive wiring 103 includes a first cobalt-metal alloy, and the first cobalt-metal alloy may be represented by Chemical Formula 1.

Co₁₋ₓM¹ₓ Chemical Formula 1

In Chemical Formula 1,

M¹ may be selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and 0<x<1.

In Chemical Formula 1, x may be in the range of greater than 0 and less than 1, for example, greater than or equal to about 0.1, for example greater than or equal to about 0.2, greater than or equal to about 0.3, and for example less than or equal to about 0.9, about 0.8, less than or equal to about 0.7, less than or equal to about 0.6, less than or equal to about 0.5, less than about 0.5, or less than or equal to about 0.45. Even if the width of the conductive wiring 103 is reduced in the above range, the resistance value of the interconnect structure may be suppressed or minimized from increasing, e.g., from increasing exponentially, and a relatively low resistance value may be obtained.

The first cobalt-metal alloy may have a cohesive energy of greater than or equal to about 4.5 eV/atom, for example, greater than or equal to about 5.0 eV/atom and less than or equal to about 10 eV/atom. When the cohesive energy is within the above range, there is no need to separately form a barrier layer to prevent diffusion of the material of the conductive wiring 103. As such, the liner layer or barrier layer may be a factor that increases the resistivity, and thus, if these layers are not present the increase in resistance of the interconnect structure may be reduced.

The first cobalt-metal alloy may have a FOM (Figure of Merit) of less than or equal to about 5.0×10⁻¹⁶ Ωm², for example less than or equal to about 4.9×10⁻¹⁶ Ωm², or less than or equal to about 4.8×10⁻¹⁶ Ωm². The first cobalt-metal alloy may have a FOM of greater than or equal to about 1.0×10⁻¹⁶ Ωm². Within the above range, the increase in resistance of the interconnect structure resulting from a decrease in the line width of the wiring layer can be alleviated or minimized. The FOM can be obtained by Ab initio calculation.

The first cobalt-metal alloy included in the conductive wiring 103 may have a hexagonal crystal structure (HCP) or a face-centered cubic crystal structure (FCC). When the conductive wiring 103 includes a first cobalt-metal alloy having a hexagonal crystal structure (HCP) or a face-centered cubic crystal structure (FCC) and the cobalt-containing auxiliary layer 1051 described below includes cobalt or a second cobalt-metal alloy having a hexagonal crystal structure, the flow of electrons can be facilitated, thereby reducing resistance in the interconnect structure.

The conductive wiring 103 may be formed using a precursor material of the first cobalt-metal alloy through chemical vapor deposition (CVD), plasma enhanced chemical vapor deposition (PECVD), physical vapor deposition (PVD), electroplating, chemical solution deposition, or electroless plating.

In order to increase the integration of semiconductor devices, the size of semiconductor devices is gradually decreasing, and accordingly, the line width of conductive wiring is also decreasing. However, there may be a problem associated with such design aspects because the resistivity increases significantly due to grain-boundary scattering and/or surface-roughness scattering when the line width or thickness of the conductive wiring is reduced. This increase in resistivity may cause defects in the conductive wiring by causing electromigration phenomena, which may damage the conductive wiring 103. Here, electromigration refers to the movement of matter by the continuous movement of ions within a conductor resulting from the transfer of momentum between conducting electrons and atomic nuclei within the metal. To prevent or reduce this increase in resistivity, a cobalt-containing auxiliary layer 1051 may be formed along one or more sidewalls (and/or bottom surface) of the trench structure before forming the conductive wiring 103.

The cobalt-containing auxiliary layer 1051 may include cobalt or a second cobalt-metal alloy represented by Chemical Formula 2.

Co_{1-y}M²_{y} Chemical Formula 2

In Chemical Formula 2,

M² is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and 0≤y<1.

The cobalt-containing auxiliary layer 1051 may include a second cobalt-metal alloy having a hexagonal crystal structure or having a hexagonal crystal structure.

In Chemical Formula 2, y may be in a range of greater than or equal to 0 and less than 1, for example, y may be in a range of greater than or equal to 0.1, for example greater than or equal to about 0.2, greater than or equal to about 0.25, or greater than or equal to about 0.3 and less than or equal to about 0.9, less than or equal to about 0.8, less than or equal to about 0.7, less than or equal to about 0.6, less than or equal to about 0.5, or less than or equal to about 0.45. Within the above range, the crystal structure of the first cobalt-metal alloy of the conductive wiring 103 can be easily controlled.

The y in Chemical Formula 2 can control the crystal structure of the first cobalt-metal alloy of the conductive wiring 103 formed adjacent thereto. For example, when y in Chemical Formula 2 is in a range of greater than or equal to 0 and less than or equal to about 0.25, for example, greater than 0 or greater than or equal to about 0.1 and less than or equal to about 0.24, or less than or equal to about 0.23, the cobalt-containing auxiliary layer 1051 may include cobalt or a second cobalt-metal alloy having a hexagonal crystal structure (HCP), and the conductive wiring 103 formed adjacent thereto may include a first cobalt-metal alloy having a hexagonal crystal structure (HCP). When y in Chemical Formula 2 is greater than or equal to about 0.25 and less than or equal to about 0.3, the cobalt-containing auxiliary layer 1051 may include a second cobalt-metal alloy having either a hexagonal crystal structure (HCP) or a face-centered cubic crystal structure (FCC), and the conductive wiring 103 may include a first cobalt-metal alloy having a hexagonal crystal structure (HCP) or a face-centered cubic crystal structure (FCC). When y in Chemical Formula 2 is in a range of greater than about 0.3 and less than 1, for example, in a range of greater than or equal to about 0.31 or greater than or equal to about 0.35 and less than or equal to 0.9 or less than or equal to 0.85, the cobalt-containing auxiliary layer 1051 may include a second cobalt-metal alloy having a face-centered cubic crystal structure (FCC), and the conductive wiring 103 may include a first cobalt-metal alloy having a face-centered cubic crystal structure (FCC). The cobalt-containing auxiliary layer 1051 and the conductive wiring 103 having such a crystal structure can suppress or reduce an increase in resistance due to a decrease in line width of the conductive wiring.

In an embodiment, the conductive wiring 103 may have the same crystal structure as the first cobalt-metal alloy and the cobalt or second cobalt-metal alloy of the cobalt-containing auxiliary layer 1051.

The second cobalt-metal alloy of the cobalt-containing auxiliary layer 1051 may include a relatively greater amount (atomic percent, at %) of cobalt than the first cobalt-metal alloy of the conductive wiring 103. For example, a difference between a cobalt content of the second cobalt-metal alloy and a cobalt content of the first cobalt-metal alloy may be greater than or equal to about 10 at %, for example greater than or equal to about 12 at %, greater than or equal to about 13 at %, greater than or equal to about 14 at %, greater than or equal to about 15 at %, greater than or equal to about 16 at %, greater than or equal to about 17 at %, greater than or equal to about 18 at %, greater than or equal to about 19 at %, or greater than or equal to about 20 at %. A difference between a cobalt content of the second cobalt-metal alloy and a cobalt content of the first cobalt-metal alloy may be less than or equal to about 60 at %. less than or equal to about 50 at %, or less than or equal to about 50 at %. Moreover, the crystal structure of the first cobalt-metal alloy can be easily controlled within the above range.

When the cobalt or second cobalt-metal alloy of the cobalt-containing auxiliary layer 1051 and the first cobalt-metal alloy of the conductive wiring 103 have the aforementioned crystal structure, they may have a lattice mismatch of less than or equal to about 5%.

The above cobalt-containing auxiliary layer 1051 may have a thickness of less than or equal to about 3 nm, for example, less than or equal to about 2.5 nm, less than or equal to about 2.0 nm, less than or equal to about 1.5 nm, or less than or equal to about 1.0 nm. The cobalt-containing auxiliary layer 1051 may have a thickness of greater than or equal to about 0.01 nm, for example about 0.02 nm, greater than or equal to about 0.03 nm, greater than or equal to about 0.04 nm, or greater than or equal to about 0.05 nm. Within the above range, it is possible to provide a crystal structure of the first cobalt-metal alloy of the conductive wiring 103 to have a relatively constant crystal structure, and prevent or reduce an increase in resistance due to a decrease in line width of the conductive wiring.

The thickness of the cobalt-containing auxiliary layer 1051 may be in a range of about 5% to about 30%, for example, greater than or equal to about 6%, greater than or equal to about 7%, greater than or equal to about 8%, greater than or equal to about 9%, or greater than or equal to about 10% and less than or equal to about 29%, less than or equal to about 28%, less than or equal to about 27%, less than or equal to about 26%, or less than or equal to about 25%, of the width of the trench structure 101a. The width of the trench structure being the distance between a surface and the opposite surface of the dielectric layer. Within the above range, it is possible to provide a crystal structure of the first cobalt-metal alloy of the conductive wiring grow with a relatively constant crystal structure, and prevent or reduce an increase in resistance due to a decrease in line width of the conductive wiring.

In the interconnect structure 100a, there is little or no need for a separate barrier layer to prevent diffusion of the conductive wiring 103 material or a liner layer to improve the adhesive strength of the conductive wiring 103.

The cobalt-containing auxiliary layer 1051 may be formed using a cobalt precursor material through chemical vapor deposition (CVD), plasma enhanced chemical vapor deposition (PECVD), physical vapor deposition (PVD), electroplating, chemical solution deposition, or electroless plating.

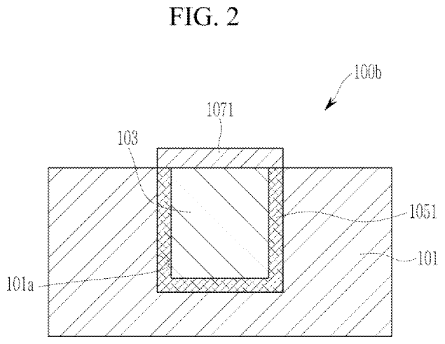

FIGS. 2, 3, and 4 are cross-sectional views of interconnect structures 100b, 100c, and 100d in accordance with different embodiments.

A cap layer may be further formed on an upper surface of the aforementioned conductive wiring 103. The cap layers 1071 and 1072 can reduce the resistance of the conductive wiring 103 and prevent electrical deterioration of the conductive wiring 103. The cap layers 1071 and 1072 may be formed on an upper surface of the conductive wiring 103 and the cobalt-containing auxiliary layer 1051. Additionally, the cap layers 1071 and 1072 may be arranged to cover a portion of the upper surface of the conductive wiring 103, the cobalt-containing auxiliary layer 1051 and an upper surface of the dielectric layer 101 (not shown).

Referring to FIG. 2, the interconnect structure 100b includes a dielectric layer 101 having a trench structure 101a structure; a cobalt-containing auxiliary layer 1051 formed along the sidewalls and the bottom of trench structure 101a; a conductive wiring 103 including a first cobalt-metal alloy within the interior of the trench structure 101a; and a cap layer 1071 formed on the cobalt-containing auxiliary layer 1051 and the conductive wiring 103.

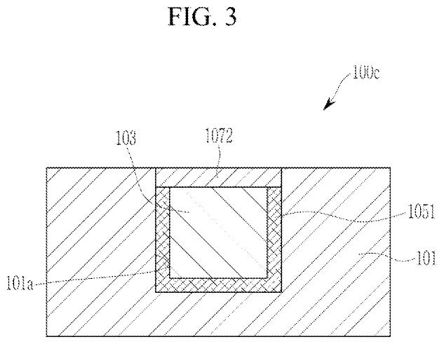

Referring to FIG. 3, the interconnect structure 100b includes a dielectric layer 101 having a trench structure 101a structure; a cobalt-containing auxiliary layer 1051 formed along the sidewalls and the bottom of trench structure 101a; a conductive wiring 103 including a first cobalt-metal alloy within the interior of the trench structure 101a; and a cap layer 1072 formed on the cobalt-containing auxiliary layer 1051 and the conductive wiring 1103.

The cap layers 1071 and 1072 may include Co, Ru, Ta, SiN, SiON, graphene, hexagonal boron nitride (h-BN), amorphous boron nitride (a-BN), AlO_{z} (0<z≤3/2), AlN, or a combination thereof.

The cap layers 1071 and 1072 may have a single-layer structure or a multilayer structure in which different materials are stacked.

The thickness of the cap layers 1071 and 1072 may be in a range of about 1 nm to about 20 nm, about 1 nm to about 10 nm, about 1 nm to about 5 nm, or about 1 nm to about 3 nm.

Before forming the cap layers 1071 and 1072, the upper surface of the cobalt-containing auxiliary layer 1051 and the conductive wiring 103 can be flattened (planarized). Here, the planarization process may include, but is not limited to, a chemical mechanical polishing (CMP) process or a grinding process, but the present disclosure is not limited thereto.

The conductive wiring having a multilayer structure of the conductive wiring 103 and the cobalt-containing auxiliary layer 1051 can prevent or minimize an expected increase in electrical resistance due to a decrease in the wiring line width and reduce or prevent defects in the wiring due to electromigration.

In the interconnect structures 100a, 100b, and 100c of FIGS. 1, 2, and 3, the cobalt-containing auxiliary layer 1051 may also serve as a seed layer for forming a conductive wiring 103. Additionally, the cobalt-containing auxiliary layer 1051 may also function as a barrier layer that prevents the material of the conductive wiring 103 from diffusing.

In an interconnect structure according to an embodiment, since a cobalt-containing auxiliary layer 1051 is formed in contact with a conductive wiring 103, there is little or no need for a separate barrier layer to prevent diffusion of a material of the conductive wiring 103 or a liner layer to improve the adhesive strength of the conductive wiring 103.

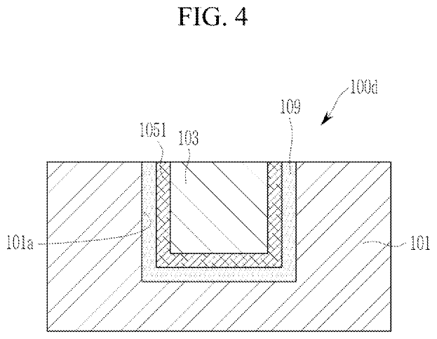

However, if necessary, a barrier layer may be further included between the dielectric layer 101 and the conductive wiring 103 or between the dielectric layer 101 and the cobalt-containing auxiliary layer 1051. A structure in which a barrier layer is additionally included in the interconnect structure of FIG. 1 is illustrated in FIG. 4. FIG. 4 is a cross-sectional view of an interconnect structure according to an embodiment.

Referring to FIG. 4, the interconnect structure 100d is formed with a structure in which a barrier layer 107 is disposed on both sidewalls and a bottom surface of a trench structure 101a of a dielectric layer 101, and the barrier layer 107 surrounds a cobalt-containing auxiliary layer 1051 and a conductive wiring 103 positioned within the trench structure 101a.

The barrier layer 107 can prevent or minimize the material of the conductive wiring 103 from diffusing into the dielectric layer 101. The barrier layer 107 may have a multilayer structure in which multiple layers including different materials are stacked. For example, the barrier layer 107 may include a first barrier layer in contact with the conductive wiring 103 and a second barrier layer in contact with the cobalt-containing auxiliary layer 1051, and the first barrier layer may include a metal or an alloy of metals and the second barrier layer may include a metal nitride or a metal oxide.

The barrier layer may include a metal, an alloy of a metal, a metal oxide, a metal nitride or a combination thereof.

The barrier layer can prevent the material of the conductive wiring 103 and/or the first cobalt-containing auxiliary layer 1053 from diffusing into the dielectric layer 101. The barrier layer may have a multilayer structure in which a plurality of layers including different materials are stacked. For example, the barrier layer may include a first barrier layer in contact with the conductive wiring 103 or the first cobalt-containing auxiliary layer 1053 and a second barrier layer in contact with the dielectric layer 101, and the first barrier layer may include a metal or an alloy of metals and the second barrier layer may include a metal nitride or a metal oxide.

The metal that can be used in the barrier layer may be selected from magnesium (Mg), aluminum (Al), scandium (Sc), titanium (Ti), vanadium (V), chromium (Cr), manganese (Mn), nickel (Ni), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), nickel (Ni), ruthenium (Ru), and a combination thereof. The metal alloy of the barrier layer may include RuTa, IrTa, etc.

The metal oxide of the barrier layer may be a compound represented by Chemical Formula 3.

MₐO_{b} Chemical Formula 3

In Chemical Formula 3,

M may be at least one selected from Mn, Al, Ti, Zr, Hf, Mg, Si, Ge, Y, Lu, La, Ta, and Sr, 0<a≤2, and 0<b≤3.

Examples of the metal oxides may include MnO, AlO_{z} (0<z≤3/2), TaO_{z} (0<z≤5/2), TiO₂, ZrO₂, HfO₂, MgO, SiO₂, GeO₂, Y₂O₃, Lu₂O₃, La₂O₃, SrO, and the like.

The metal nitride of the above barrier layer may include tantalum nitride (TaN), titanium nitride (TiN), ruthenium nitride (RUN), tungsten nitride (WN), aluminum nitride (AlN), IrTaN, TiSiN, and the like.

As described above, since the first cobalt-containing auxiliary layer 1053 can function as a barrier layer, the barrier layer may not be included.

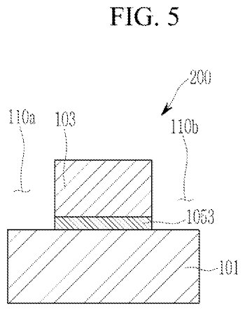

If the upper surface is a flat substrate, the multilayer wiring structure of the conductive wiring and the cobalt-containing auxiliary layer may have empty spaces on both sides. This structure is illustrated in FIG. 5. FIG. 5 is a cross-sectional view of an interconnect structure according to an embodiment.

Referring to FIG. 5, the interconnect structure 200 has a multilayer structure in which a cobalt-containing auxiliary layer 1053 and a conductive wiring 103 are stacked on a dielectric layer 101, and empty spaces 110a and 110b exist on both sides of the multilayer structure. Although FIG. 5 illustrates a structure in which a cobalt-containing auxiliary layer 1053 is formed on a bottom surface of a conductive wiring 103, the cobalt-containing auxiliary layer 1053 may be disposed on a bottom surface and both sidewalls of the conductive wiring 103, or may be disposed only on the sidewalls.

In the interconnect structure 200 of FIG. 5, the cobalt-containing auxiliary layer 1053 may serve as a seed layer for forming a conductive wiring 103.

In FIG. 5, the empty spaces 110a and 110b may be filled with air, etc., and if the empty spaces 110a and 110b are an air gap filled with air, the air gap itself can act as a dielectric.

The above interconnect structure 200 can alleviate an increase in electrical resistance due to a decrease in the line width of conductive wiring due to high integration of semiconductor devices and reduce or prevent defects due to electromigration caused by an increase in electrical resistance within the interconnect structure.

The interconnect structures 100a, 100b, 100c, 100d, and 200 described above include a conductive wiring and a cobalt-containing auxiliary layer, however if the composition of the first cobalt-metal alloy of the conductive wiring 103 is adjusted to a specific range, an expected increase in resistance due to a decrease in the line width of the interconnect structure can be reduced or minimized.

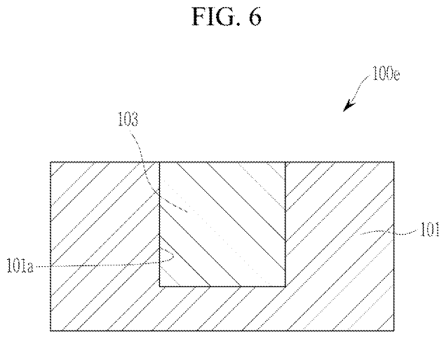

This structure is illustrated in FIG. 6. FIG. 6 is a cross-sectional view of an interconnect structure according to an embodiment.

In this case, the interconnect structure 100e includes a dielectric layer 101; and a conductive wiring 103 including a first cobalt-metal alloy within a trench structure 101a of the dielectric layer 101, and the first cobalt metal alloy may be represented by Chemical Formula 1A.

Co_{1-z}M¹_{z} Chemical Formula 1A

In Chemical Formula 1A, z is in a range of greater than or equal to about 0.2 and less than about 0.5, for example greater than or equal to about 0.3 and less than or equal to about 0.45, and

M¹ is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof.

When the range of z in Chemical Formula 1A is adjusted to a range of greater than or equal to about 0.2 and less than about 0.5, for example greater than or equal to about 0.3 and less than or equal to about 0.45, an expected increase in resistance due to a decrease in the line width of the interconnect structure can be reduced or minimized.

When the composition of the first cobalt-metal alloy of the conductive wiring 103 is adjusted to the above range and a cobalt-containing auxiliary layer (not shown) is further disposed between the dielectric layer 101 and the conductive wiring, the expected increase in resistance due to a decrease in the line width of the interconnect structure can be reduced or minimized more effectively, i.e., an even greater decrease in the expected increase in resistance.

The aforementioned interconnect structures 100a, 100b, 100c, 100d, 100e, and 200 may constitute an electronic device. For example, the electronic device may include a semiconductor device, in which case the interconnect structures 100a, 100b, 100c, 100d, 100e, and 200 may be applied to a BEOL (Back End Of Line) structure of the semiconductor device, etc. The semiconductor device may include at least one of a transistor, a capacitor, a diode, and a resistor. In addition, the interconnect structures 100a, 100b, 100c, 100d, 100e, and 200 may be applied to various electronic devices.

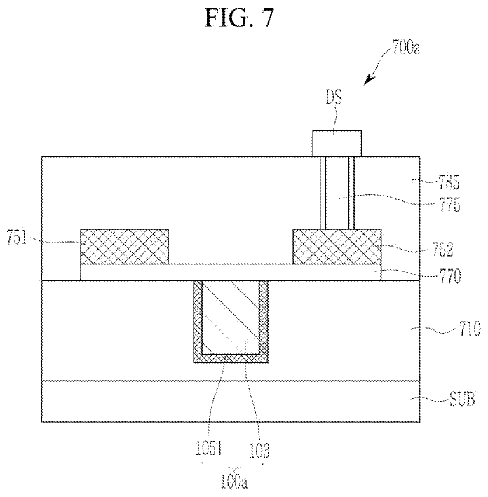

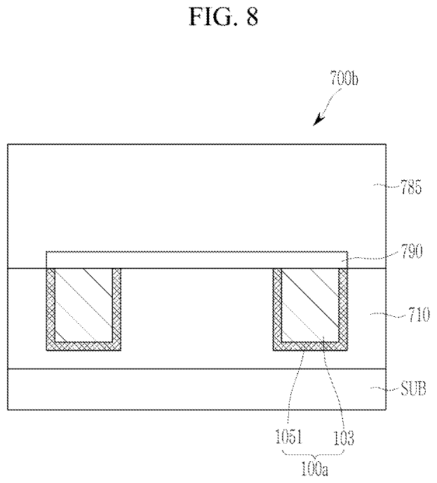

Hereinafter, an electronic device including the interconnect structures described above will be described with reference to FIGS. 7 and 8.

FIGS. 7 and 8 are cross-sectional views of electronic devices according to some embodiments.

Referring to FIG. 7, in an embodiment, the electronic device 700a may be a transistor connected to a data storage DS. The electronic device 700a may include a substrate SUB, an oxide dielectric layer 710, and a conductive wiring 103 and a cobalt-containing auxiliary layer 1051 are present within a trench of the oxide dielectric layer 710. The conductive wiring 103 and cobalt-containing auxiliary layer 1051 are formed with the same structure as that shown in FIG. 1. Alternatively, in other embodiments, a transistor as is applied in FIG. 7, the interconnect structure 100a may be any one of the interconnect structures illustrated in FIGS. 2 to 5.

The gate insulating layer 770 is formed on the oxide dielectric layer 710. The source electrode 751 and the drain electrode 752 are arranged spaced apart from each other on the gate insulating layer 770. The conductive wiring 103 may be configured to operate as a gate electrode of an electronic element 770a.

The electronic device 700a may further include an insulating layer 785, such as silicon oxide, covering the source electrode 751, the gate insulating layer 770, and the drain electrode 752, and a data storage (DS) (e.g., a capacitor) may be on the insulating layer 785. Contact 775 including an electrically conductive material such as a metal or a metal alloy may connect data storage DS and drain electrode 752.

Referring to FIG. 8, in an embodiment, the electronic device 700b is different from the electronic device 700a shown in FIG. 7 in that the gate insulating layer 770, the contact 775, the source electrode 751, the drain electrode 752, and the data storage DS are omitted. Additionally, the oxide dielectric layer 710 includes two conductive wiring within respective trenches of the dielectric layer 710 spaced apart from the other, and each of the trenches is formed in the same structure as the interconnect structure in FIG. 1. That is, each of the trenches may include a conductive wiring 103 and a cobalt-containing auxiliary layer 1051.

The upper conductive layer 790 is formed on the oxide dielectric layer 710 and contacts the upper surface of the conductive wiring 103 in each interconnect structure, so that the interconnect structures are electrically connected to each other. The upper conductive layer 790 may include a conductive material such as a metal, a metal alloy, or a doped semiconductor. Alternatively, in other embodiments, the interconnect structure 100a as applied in FIG. 8, may be any one of the interconnect structures illustrated in FIGS. 2 to 5.

Hereinafter, the embodiments are illustrated in more detail with reference to examples. However, the following examples are for illustrative purposes only and do not limit the scope of the rights.

### Evaluation 1: Resistance Measurement According to Alloy Composition of Cobalt-Nickel Alloy of Stacked Structure

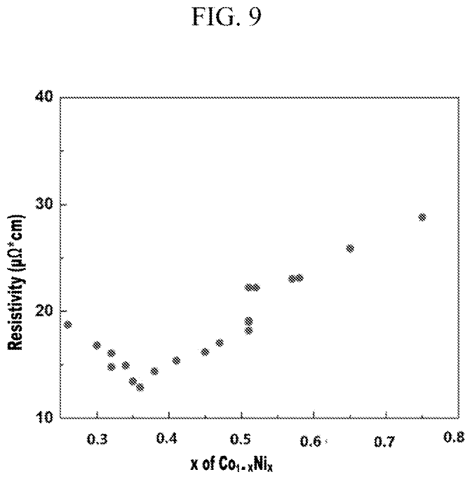

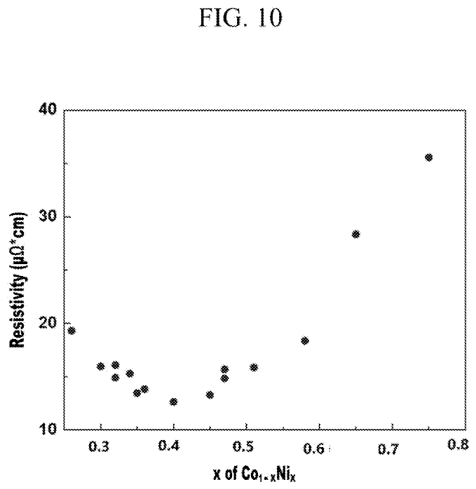

A cobalt-nickel alloy is deposited at 250° C. by sputtering on each of the sapphire c-plane (0001) and sapphire a-plane (11-20) with a thickness of 430 micrometers (μm) to form a film with an average thickness of 10 nm. The resistance value of cobalt-nickel alloy (Co₁₋ₓNiₓ) according to the x value of Chemical Formula 1 (or the z value in Chemical Formula 1A) is measured using a 4-point probe method and is shown in FIGS. 9 and 10. FIG. 9 is a graph showing the resistance value according to the x value of a cobalt-nickel alloy (Co₁₋ₓNiₓ) formed on a sapphire c-plane (0001) substrate, and FIG. 10 is a graph showing the resistance value according to the x value of a cobalt-nickel alloy (Co₁₋ₓNiₓ) formed on a sapphire a-plane (11-20) substrate. Referring to FIGS. 9 and 10, the resistance value decreases significantly when the x value (or z value) is greater than or equal to 0.2 and less than about 0.5.

### Evaluation 2: Resistance Measurement According to the Thickness of the Stacked Structure

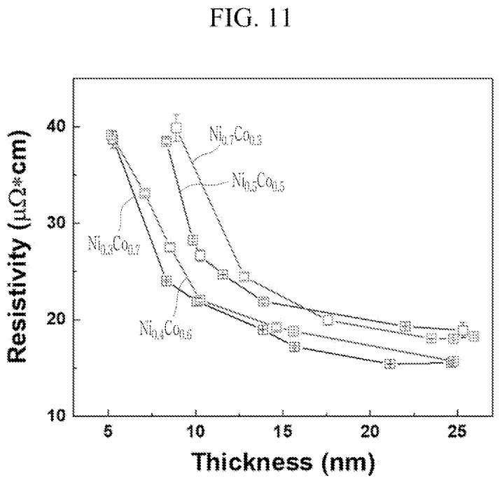

A film is formed by depositing a cobalt-nickel alloy by sputtering at 250° C. on a quartz substrate having a thickness of 430 μm. The resistance value according to the film thickness is measured using the 4-point probe method and is shown in FIG. 11. FIG. 11 is a graph showing the results of resistance value measurements according to the thickness of a cobalt-nickel alloy formed on a quartz substrate. Referring to FIG. 11, when the alloy compositions of the cobalt-nickel alloy are Co_{0.3}Ni_{0.7} and Co_{0.4}Ni_{0.6}, significantly lower resistance values at a thickness of 10 nm or less are shown compared to when the alloy compositions of the cobalt-nickel alloy are Co_{0.5}Ni_{0.5} and Co_{0.7}Ni_{0.3}.

### Evaluation 3: Resistance Measurement According to the Thickness of the Stacked Structure

A stacked structure according to Comparative Example 1 is manufactured by forming a Cu/TaN (average thickness of Cu: 1.5 nm) film by sputtering at 250° C. on a sapphire a-plane (11-20) substrate.

A stacked structure according to Example 1 is manufactured by forming a Co_{0.6}Ni_{0.4} alloy layer by sputtering at 250° C. on a sapphire a-plane (11-20) substrate.

A stacked structure according to Example 2 is manufactured by forming a Co alloy layer (cobalt-containing auxiliary layer, average thickness: 1.65 nm) by sputtering at 250° C. on a sapphire a-plane (11-20) substrate and forming a Co_{0.6}Ni_{0.4} alloy layer thereon.

A stacked structure according to Example 3 is manufactured by forming a Co alloy layer (cobalt-containing auxiliary layer, average thickness: 1.65 nm) by sputtering at 25° C. on a sapphire a-plane (11-20) substrate and forming a Co_{0.6}Ni_{0.4} alloy layer thereon.

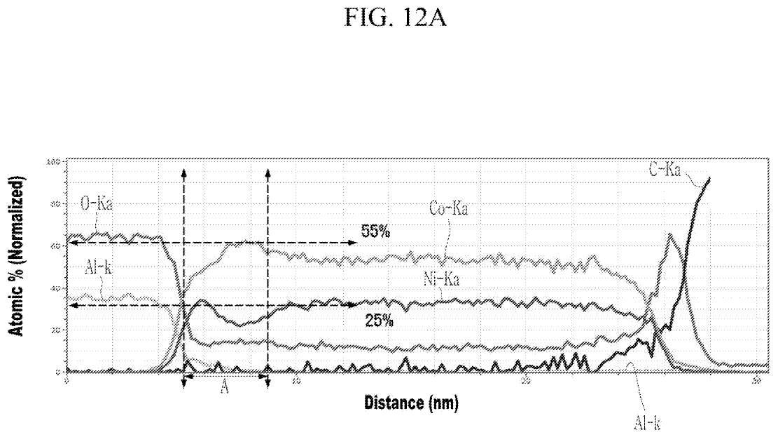

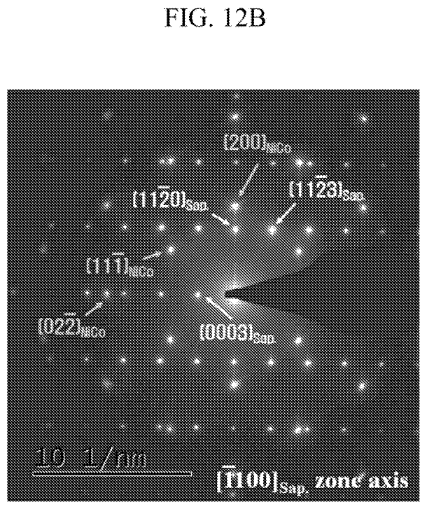

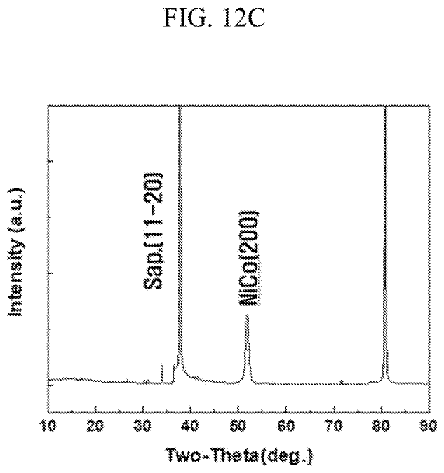

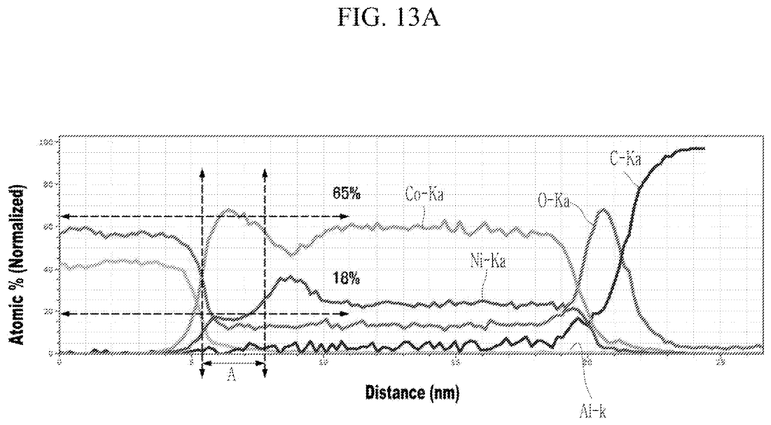

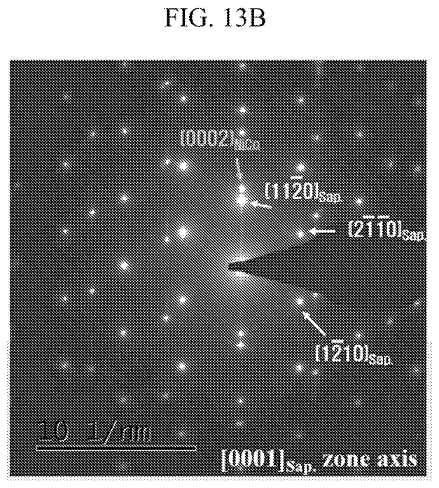

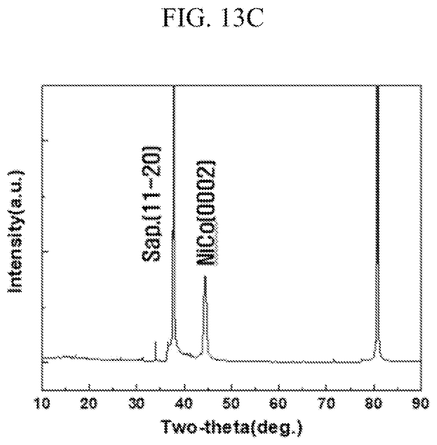

The stacked structures according to the above Examples 2 and 3 are analyzed for elements and structures by transmission electron microscopy-energy dispersive X-ray spectroscopy (TEM-EDS) and X-ray diffraction analysis (light source: Cu Kα, 2θ=10° to 90°), and the results are shown in FIGS. 12a to 13c. FIG. 12A is a graph showing the results of elemental analysis of a stacked structure according to Example 2 using transmission electron microscopy-energy dispersive X-ray spectroscopy (TEM-EDS), FIG. 12B is a drawing showing the crystal structure of a Co_{0.6}Ni_{0.4} alloy layer, and FIG. 12C is a graph showing the results of X-ray diffraction analysis of the Co_{0.6}Ni_{0.4} alloy layer. FIG. 13A is a graph showing the results of elemental analysis of a stacked structure according to Example 3 using transmission electron microscopy-energy dispersive X-ray spectroscopy (TEM-EDS), FIG. 13B is a drawing showing the crystal structure of a Co_{0.6}Ni_{0.4} alloy layer, and FIG. 13C is a graph showing the results of X-ray diffraction analysis of the Co_{0.6}Ni_{0.4} alloy layer. In FIGS. 12a and 13a, 0 on the horizontal axis indicates the starting point of the EDS line scan, and Distance indicates the distance from this starting point to the surface. From the elemental analysis results in FIGS. 12a and 13a, it can be predicted that the “A” region is a cobalt-containing auxiliary layer.

Referring to FIG. 12A, the EDS analysis result of the cobalt-containing auxiliary layer (area A) of the stacked structure according to Example 2 shows that Co:Ni is 1:0.45, and from this, it can be seen that the alloy composition of the cobalt-containing auxiliary layer is Co_{0.69}Ni_{0.31}, and referring to the TEM analysis result of FIG. 12b and the XRD analysis result of FIG. 12c, it can be confirmed that the crystal structure of the Co_{0.6}Ni_{0.4} alloy layer formed on the cobalt-containing auxiliary layer is an FCC structure.

Referring to FIG. 13A, the EDS analysis result of the cobalt-containing auxiliary layer (area A) of the stacked structure according to Example 3 shows that Co:Ni is 1:0.28, and from this, it can be seen that the alloy composition of the cobalt-containing auxiliary layer is Co_{0.79}Ni_{0.21}. Referring to the TEM analysis result of FIG. 13B and the XRD analysis result of FIG. 13C, the crystal structure of the Co_{0.6}Ni_{0.4} alloy layer formed on the cobalt-containing auxiliary layer is an HCP structure.

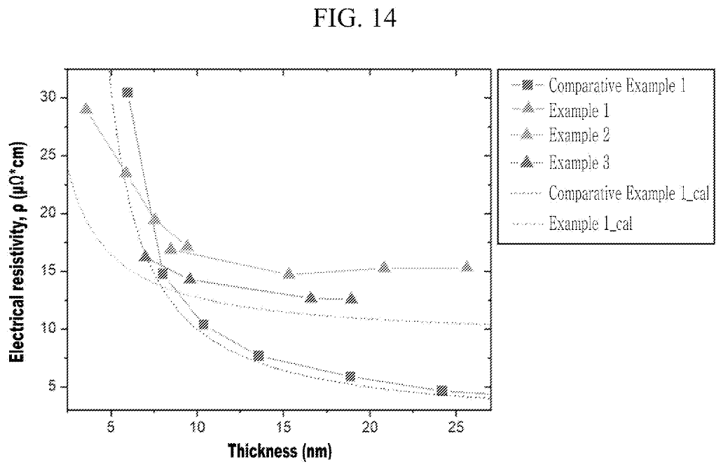

The resistance according to the thickness of the stacked structures according to Comparative Example 1 and Examples 1, 2, and 3 is measured, and the results are shown in FIG. 14. FIG. 14 is a graph showing the results of resistance measurements according to the thickness of stacked structures according to Comparative Example 1 and Examples 1, 2, and 3. Referring to FIG. 14, the stacked structures according to Examples 1, 2, and 3 do not exhibit a relatively large increase in resistance at a thickness of less than 10 nm. In particular, the stacked structure according to Example 2 exhibited low resistance even at 5 nm or less. In comparison, the resistance of the stacked structure according to Comparative Example 1 increases rapidly at a thickness of 10 nm or less.

The stacked structures of Example 1 and Comparative Example 1 are plotted by measuring the resistance of the stacked structures having a thickness of 6 nm. In order to find out the resistance tendency when the thickness is less than 6 nm, the resistance values calculated by the Ab initio program for the stacked structures of Example 1 and Comparative Example 1 are also shown in FIG. 14 (Example 1_cal and Comparative Example 1_cal). Referring to FIG. 14, the stacked structure according to Example 1 does not show a large increase in resistance with a thickness decrease of less than 6 nm, but the stacked structure according to Comparative Example 1 shows a large increase in resistance with a thickness decrease.

While this disclosure has been described in connection with what is presently considered to be practical example embodiments, it is to be understood that the invention is not limited to the disclosed embodiments, but, on the contrary, is intended to cover various modifications and equivalent arrangements included within the spirit and scope of the appended claims.

<Description of symbols>

100a, 100b, 100c, 100d, 100e, 200: interconnect structure
101: dielectric layer
101a: trench structure
SUB: substrate
103: conductive wiring
1051, 1053: cobalt-containing
auxiliary layer
110a, 110b: empty space
700a, 700b: electronic device
710: oxide dielectric layer
770: gate insulating layer
751: source electrode
752: drain electrode
DS: data storage
785: insulating layer
790: upper conductive layer

What is claimed is:

1. An interconnect structure comprising:
a dielectric layer;
a conductive wiring comprising a first cobalt-metal alloy within a trench structure of the dielectric layer; and
a cobalt-containing auxiliary layer between the conductive wiring and the dielectric layer
wherein the cobalt-containing auxiliary layer comprises cobalt or a second cobalt-metal alloy.

2. The interconnect structure of claim 1, wherein
the dielectric layer comprises a dielectric having a dielectric constant of less than or equal to about 3.6.

3. The interconnect structure of claim 1, wherein
the dielectric layer comprises a metal oxide, a carbon-doped metal oxide, a metal carbide, a hydrogenated metal carbide, a metal nitride, a metal oxynitride, or a combination thereof.

4. The interconnect structure of claim 1, wherein
the first cobalt-metal alloy included in the conductive wiring represented by Chemical Formula 1:
Co₁₋ₓM¹ₓ Chemical Formula 1
wherein, in Chemical Formula 1, M¹ is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and
0<x<1.

5. The interconnect structure of claim 1, wherein
the first cobalt-metal alloy has a cohesive energy of greater than or equal to about 4.5 eV/atom.

6. The interconnect structure of claim 1, wherein
the first cobalt-metal alloy has a figure of merit of less than or equal to about 5.0×10⁻¹⁶ Ωm².

7. The interconnect structure of claim 1, wherein
the cobalt-containing auxiliary layer comprises cobalt or a second cobalt-metal alloy represented by Chemical Formula 2:
Co_{1-y}M²_{y} Chemical Formula 2
wherein, in Chemical Formula 2,
M² is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and
0≤y<1.

8. The interconnect structure of claim 1, wherein
the first cobalt-metal alloy has a hexagonal crystal structure or a face-centered cubic crystal structure.

9. The interconnect structure of claim 1, wherein
the cobalt-containing auxiliary layer comprises a second cobalt-metal alloy having a hexagonal crystal structure.

10. The interconnect structure of claim 7, wherein
the cobalt-containing auxiliary layer comprises cobalt or a second cobalt-metal alloy in which y of Chemical Formula 2 is in a range of greater than or equal to 0 and less than about 0.25, and
the conductive wiring comprises a first cobalt-metal alloy having a hexagonal crystal structure (HCP).

11. The interconnect structure of claim 7, wherein
the cobalt-containing auxiliary layer comprises a second cobalt-metal alloy in which y of Chemical Formula 2 is in a range of greater than or equal to about 0.25 and less than or equal to about 0.3, and
the conductive wiring comprises a first cobalt-metal alloy having either a hexagonal crystal structure or a face-centered cubic crystal structure.

12. The interconnect structure of claim 7, wherein
the cobalt-containing auxiliary layer comprises a second cobalt-metal alloy in which y of Chemical Formula 2 is in a range of greater than about 0.3 and less than 1, and
the conductive wiring comprises a first cobalt-metal alloy having a face-centered cubic crystal structure.

13. The interconnect structure of claim 1, wherein
the second cobalt-metal alloy of the cobalt-containing auxiliary layer comprises a greater atomic percent of cobalt than the atomic percent of cobalt of the first cobalt-metal alloy of the conductive wiring.

14. The interconnect structure of claim 13, wherein
a difference between the atomic percent of cobalt in the second cobalt-metal alloy to the atomic percent of cobalt in the first cobalt-metal alloy is greater than or equal to about 10 at %.

15. The interconnect structure of claim 1, wherein
the cobalt-containing auxiliary layer has a thickness of less than or equal to about 3 nm.

16. The interconnect structure of claim 1, wherein
the trench structure of the dielectric layer has a width of less than or equal to about 10 nm and an aspect ratio of greater than or equal to about 3.

17. The interconnect structure of claim 1, wherein
the cobalt-containing auxiliary layer is disposed on two sidewalls or a bottom surface, or both of the conductive wiring.

18. The interconnect structure of claim 1, further comprising
a barrier layer disposed between the cobalt-containing auxiliary layer and the dielectric layer along one or more sidewalls of the trench structure.

19. An interconnect structure comprising:
a dielectric layer;
a conductive wiring comprising a first cobalt-metal alloy within a trench structure of the dielectric layer;
wherein the first cobalt metal alloy is represented by Chemical Formula 1A
Co_{1-z}M¹_{z} Chemical Formula 1A
wherein, in Chemical Formula 1A,
M¹ is selected from nickel (Ni), ruthenium (Ru), aluminum (Al), tungsten (W), molybdenum (Mo), titanium (Ti), tantalum (Ta), nickel (Ni), platinum (Pt), chromium (Cr), rhodium (Rh), iridium (Ir), palladium (Pd), osmium (Os), gold (Au), niobium (Nb), vanadium (V), scandium (Sc), erbium (Er), lanthanum (La), or a combination thereof, and 0.2≤z<0.5.

20. An electronic device comprising an interconnect structure,
wherein the interconnect structure comprises
a dielectric layer;
a conductive wiring comprising a first cobalt-metal alloy within a trench structure of the dielectric layer; and
a cobalt-containing auxiliary layer between the conductive wiring and the dielectric layer
wherein the cobalt-containing auxiliary layer comprises cobalt or a second cobalt-metal alloy.
